(19) United States
(12) Patent Application Publication
(10) Pub. No.: US 2004/0009425 A1
(43) Pub. Date: Jan. 15, 2004

(54) Radiation durable organic compounds with high transparency at 157 nm, and method for preparing

(76) Inventors: Roger Harquail French, Wilmington, DE (US); David Joseph Jones, Wilmington, DE (US); Robert Clayton Wheland, Wilmington, DE (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/382,695

(22) Filed: Mar. 6, 2003

Related U.S. Application Data
(60) Provisional application No. 60/361,999, filed on Mar. 6, 2002.

(51) Int. Cl. G03F 7/004; G03F 7/20; G03F 7/26

(52) U.S. Cl. 430/270.1; 430/311; 430/322; 430/327

(57) ABSTRACT

This invention concerns radiation durable organic compositions which are well-suited for use in 157 nm lithography by virtue of their high transparency and excellent radiation durability, and to a process for the preparation thereof.

### FIELD OF THE INVENTION

This invention is directed to the development of materials suitable for use in the fabrication of shaped articles by photolithographic techniques, more specifically to the fabrication of circuits by photolithography in the region of the electromagnetic spectrum known as the vacuum ultraviolet. Most specifically, this invention is directed to photolithography at wavelengths below 260 nm, particularly at 157 nm and 193 nm. In particular, this invention is directed to new organic compositions which are particularly well-suited for use in vacuum ultraviolet photolithography by virtue of their high transparency and excellent photochemical stability, and to a process for the preparation thereof.

### TECHNICAL BACKGROUND OF THE INVENTION

As the electronics industry moves to adapt the methods of photolithography to the fabrication of ever-smaller circuit elements, resort is made to ever-smaller wavelengths of light in order to achieve the higher resolution images required.

Photolithographic processes employing wavelengths in the so-called “vacuum ultra-violet” (VUV) are now under development, with considerable attention being focused on 157 nanometer (nm) and 193 nm photolithography. Vacuum ultraviolet radiation is of sufficiently high energy to break chemical bonds in some normally stable materials resulting in the formation of highly reactive free-radicals. It will be appreciated by one of skill in the art that the generation of a small number of free radicals can have catastrophic effects on the chemical stability of the host material by virtue of a free-radical chain reaction. The role of free-radicals in photochemical degradation of materials is well known. There are many types of free radicals, including hydroxyl radicals, oxygen radicals, and organic radicals. These free radicals are generated when sufficient energy is absorbed by a precursor molecule to cause it to dissociate non-ionically, forming species of neutral charge but sporting an unpaired electron.

Titze in Photodissoziation von H₂O bei 157 nm, Max Planck Inst., Gottingen, Germany, 1984, discloses photolysis of water at 157 nm to form hydrogen and hydroxide radicals.

A. C. Fozza, J. E. Klemberg-Sapieha, and M. R. Wertheimer, Plasmas and Polymers, Vol. 4, No 2/3, 1999, pages 183 to 206, discusses oxygen's undergoing photo-dissociation to activated oxygen atoms at wavelengths less than 170 nm. Also disclosed are bond breaking reactions that occur in the vacuum ultraviolet with polyethylene, polystyrene, and polymethymethacrylate. V. N. Vasilets, I. Hirata, H. Iwata, Y. Ikada, Journal of Polymer Science: Part A: Polymer Chemistry, Vol 36, 2215-2222 (1998) discusses radical formation and photooxidation when tetrafluoroethylene/hexafluoropropylene copolymer is irradiated with 147 nm light:

N. Ichinose and S. Kawanishi, Macromolecules, 1996, 29, 4155-4157 discloses the irradiation of polymers such as Teflon® PTFE, Teflon® FEP, Teflon® PFA, Tefzel®, and polyvinylidene fluoride with light at 185, 193, 248, and 254 nm. When the polymer surface was in contact with nitrogen-purged water, extensive surface reaction was detected. The surface reactivity was particularly apparent at 185, 193, and 248 nm but much less so if at all at 254 nm. Perfluorinated polymers such as Teflon® PTFE and Teflon® PFA reacted more readily than partially fluorinated polymers such as Tefzel® and polyvinylidene fluoride. No significant photochemistry was observed in the absence of water. Saturation of the water with oxygen also completely inhibited the surface chemistry. It is further taught that water starts to absorb around 190 to 200 nm and that photons of wavelengths shorter than 191-207 nm have sufficient energy to exceed the threshold ionization energy of liquid water.

It is very well-known in the art that oxygen radicals, which are produced by numerous means, are highly reactive with a tremendous range of materials, causing degradation both in the presence and absence of water, depending upon the specific circumstances. Prevention of oxidation is a large and complex art in itself, with a long history.

Considerable emphasis in the art has been placed on identifying organic polymeric compositions suitable for use in the VUV. See for example WO 0185811 and WO 137044 which disclose fluorinated polymeric compositions having high transparency at 157 nm. Considerably less emphasis has been placed upon the low molecular weight organic compositions which are employed as solvents for the polymer during spin coating, as plasticizers for polymeric films, or in an adhesive formulation. Alternatively, an organic fluid or gel may be employed as an immersion medium in immersion photolithography, as disclosed for example by Switkes and Rothschild (J. Vac. Sci. Technol. B, 19 (6), 2353-6, November/December 2001) in which a fluid medium is used between the projection lens of the optical stepper and the photoresist coated substrate (typically a silicon wafer) which will receive and detect the photolithographic image. But, whether a polymer or a low molecular organic composition, if the material resides in the light path between the source and the target, the material needs to be transparent and durable.

For a material to be useful in VUV photolithography it is necessary but not sufficient that it exhibit high transparency, particularly at 157 nm and 193 nm; it must also exhibit high photochemical stability known in the art as radiation durability. Radiation durability is the property of a material to retain transparency upon being subject to exposure to electromagnetic radiation of a particular frequency. In many aspects of photolithography, commercial considerations require a transparent material to retain a high degree of transparency while being subject to a significant cumulative dose of radiation.

Hydrofluorocarbons having the general formula CₙF₂ₙ₊₂₋ₓHₓ are well known in the art, and are readily prepared by known methods. One such method is the addition of hydrogen across the double bond of a fluoroolefin or a hydrofluorocarbon olefin using nickel or palladium as a catalyst as described in M. Hudlicky, Chemistry of Organic Fluorine Compounds, 2^{nd} Edition, John Wiley and Sons, New York, 1976 pages 174 and 175. In the alternative, said hydrofluorocarbons may be prepared by the reduction of Br, Cl, and I atoms in fluorocarbons or hydrofluorocarbons to H with inorganic reducing agents such as LiAIH4 or Zn as described in Hudlicky, op. cit., page 182 or alternatively on page 189. In yet another method, said hydrofluorocarbons may be prepared using organic reducing agents such as tributyltinhydride as described in Hudlicky, op. cit., page 197.

F[CF(CF₃)CF₂O]nCF₂CF₃, is known in the art, as described in, Modern Fluoropolymers, J. Scheirs, editior Chapter 24, “Perfluoropolyethers (Synthesis, Characterization, and Applications)” John Wiley & Sons, New York, 1997. F[CF(CF₃)CF₂O]ₙCFHCF₃ where n=1 to 5 comes from an intermediate in the synthesis of F[CF(CF₃)CF₂O]nCF₂CF₃ in which a —COOH end group has been thermolysed to hydrogen rather than converted to —F with fluorine gas. X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched is a known variation of F[CF(CF₃)CF₂O]nCF₂CF₃, also described in Modern Fluorpolymers, op. cit. HCF₂(OCF₂)ₙ(OCF₂CF₂)ₘOCF₂H where n+m=1 to 8 is a variation of the synthesis of said X—R_{f}^{a}[OR_{f}^{b}]nOR_{f}^{c}Y in which the end groups are not fluorinated but rather diverted to other chemistry as described in Modern Fluoropolymers, op. cit., on p. 441 happens to show end groups being reduced to CH2OH rather than converted to H). Not all of the variations implied by the generic formulas may be known or easily made: for example Class ii where one has H[CF(CF₃)CF₂O]ₙCF₂H.

CF₃CH₂CF₂CH₃ is known to be synthesized by reacting CCl₄ and CH₂=CClCH₃ to give CCl₃CH₂CCl₂CH₃, and then replacement of the chlorines by treatment in hydrofluoric acid. See R. Bertocchio, A. Lantz, L. Wedlinger, Chem. Abstracts 127:161495.

### SUMMARY OF THE INVENTION

The present invention provides for an organic composition characterized by an absorbance/micrometer of <1 at wavelengths from 140 to 260 nm, said composition comprising less than 20 parts per million of water, less than 90 ppm of oxygen, and one or more compounds selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched

in which there are more fluorines than hydrogens, no runs of adjacent C—H bonds longer than two are present, no —CH₂CH₃ radicals are present and no sequences with hydrogen on both sides of an ether oxygen (CH—O—CH) are present;

iii) CₙF₂ₙ₋ᵥ₊₂Hᵥ wherein n=2 to 10, v<n+1, the number of fluorines equals or exceeds the number of hydrogens, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen.

The present invention further provides a process for preparing an organic composition characterized by an absorbance/micrometer of <1 at wavelengths from 140 to 260 nm, comprising subjecting to treatment with one or more means for extracting one or more photochemically active species, a compound selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched in which there are more fluorines than hydrogens, no runs of adjacent C—H bonds longer than two are present, no —CH₂CH₃ radicals are present and no sequences with hydrogen on both sides of an ether oxygen (CH—O—CH) are present;

iii) CₙF₂ₙ₋ᵥ₊₂Hᵥ wherein n=2 to 10, v<n+1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

x) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present, and no runs of adjacent C—F bonds longer than 6 (CF—CF—CF—CF—CF—CF), and no C—H bonds immediately adjacent to either nitrogen or oxygen;

at least until the desired concentration of said one or more photochemically active species is achieved.

This invention further includes a process for forming an optical image on a substrate, the process comprising:

a) radiating electromagnetic radiation from a source capable of radiating electromagnetic radiation in the range of 140-260 nm;

b) receiving said radiation on a target disposed to receive at least a portion of said radiation; and

wherein one or more optically transparent compositions is disposed between said radiation source and said target, at least one of said optically transparent compositions comprising a composition comprising less than 20 parts per million of water, less than 90 parts per million of oxygen, and one or more compounds selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched in which there are more fluorines than hydrogens, no runs of adjacent C—H bonds longer than two are present, and no sequences with hydrogen on both sides of an ether oxygen (CH—O—CH) are present;

iii) CₙF₂ₙ₋ᵥ₊₂Hᵥ wherein n=2 to 10, v<n+1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen.

This invention further includes a process for forming an optical image on a substrate, the process comprising:

radiating electromagnetic radiation from a source capable of radiating electromagnetic radiation in the range of 140-260 nm;

receiving said radiation on a target disposed to receive at least a portion of said radiation; and

wherein one or more optically transparent compositions is disposed between said radiation source and said target, at least one of said optically transparent compositions comprising a composition treated with one or more means for extracting one or more photochemically active species, the composition comprising one or more compounds selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched

in which there are more fluorines than hydrogens, no runs of adjacent C—H bonds longer than two are present, no —CH₂CH₃ radicals are present and no sequences with hydrogen on both sides of an ether oxygen (CH—O—CH) are present;

iii) CₙF_{2n-y+2}Hᵥ wherein n=2 to 10, v<n+1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen.

This invention further includes a process for forming an optical image on a substrate, the process comprising:

radiating electromagnetic radiation from a source capable of radiating electromagnetic radiation in the range of 140-260 nm;

receiving said radiation on a target disposed to receive at least a portion of said radiation; and

wherein at least one of said target or said source is immersed in one or more optically transparent fluorinated organic liquids characterized by an absorbance per micrometer of <5 disposed between said radiation source and said target, at least one of said optically transparent fluorinated organic compounds having been subject to treatment with one or more means for extracting one or more photochemically active species.

### BRIEF DESCRIPTION OF THE DRAWINGS

FIG. 1 shows the schematic layout of the apparatus employed for exposing a test specimen to 157 nm laser irradiation.

FIG. 2 shows the light path involved in the 157 nm laser irradiation of a specimen.

FIG. 3 is a schematic drawing of the Herrick DLC liquid specimen cell, showing the annular spacers, windows and related parts.

FIG. 4 shows the relative spectral transmittance of H-Galden® ZT85 as a function of laser irradiation dose as described in Example 4.

FIG. 5 shows the relative spectral transmittance of H-Galden® ZT85 as a function of laser irradiation dose as described in Example 5.

FIG. 6 shows the relative spectral transmittance of H-Galden® ZT85 as a function of laser irradiation dose as described in Example 6.

### DETAILED DESCRIPTION OF THE INVENTION

The present invention is directed to transparent fluorinated organic materials which have been found to be particularly well-suited for employment in VUV photolithography. While broadly directed to applications in the wavelength range of 140 to 260 nm, the two wavelengths of primary interest at the present state of technological development are at 157 nm and 193 nm. 157 nm electromagnetic radiation, by virtue of its shorter wavelength, represents a more severe condition than does 193 nm.

While the methods and principles taught herein are applicable to transparent fluorinated organic materials suitable for both 157 nm and 193 nm photolithography, one of skill in the art will appreciate that one or another of the specific compositions comprehended herein may be better suited for use at one or the other of 157 nm or 193 nm wavelengths. In the course of the discussion following hereinbelow, the term “157 nm or 193 nm” will be used throughout to indicate that the materials comprehended may be well suited to use at either one of the wavelengths, or may be useful at both wavelengths. Thus, for the purpose of the present invention, the term “or” should not be taken as limiting to only 157 nm or only 193 nm, but may also be taken to mean “or both” as well.

In the practice of the present invention certain compositions have been found to exhibit good transparency at 157 nm, 193 nm, or both. These compositions comprise compounds selected from the group consisting of:

i) cyclic, linear, or branched hydrofluorocarbons having ? to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{c}, and R_{f}^{c} are 1 to 3 carbon fluorocarbon radicals, linear or branched in which there are more fluorines than hydrogens, no runs of adjacent C—H bonds longer than two are present, and no sequences with hydrogen on both sides of an ether oxygen (CH—O—CH) are present;

iii) CₙF₂ₙ₋ᵥ₊₂Hᵥ wherein n=2 to 10, v<n+1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

ix) cyclic, linear, or branched perfluorocarbon and hydrofluorocarbon amines, and ether-amines in which there are more fluorines than hydrogens, no runs of hydrogen longer than two (CH—CH), no runs of adjacent C—F bonds longer than 6 (CF—CF—CF—CF—CF—CF), and no C—H bonds immediately adjacent to either nitrogen or oxygen.

The above compounds are characterized by desirably low absorbance in the region from 140-260 nm. Table 1 shows the measured absorbance at 157 nm for a selection of commercially available compounds which are comprehended among the compositions hereinabove cited.

TABLE 1
Absorbance/Micrometer (A/μm)

| | Commercial | | | A/μm @ |
|---|---|---|---|---|
| Ex | Name | Vendor | Chemical Formula | 157 nm |
| 1 | Fluorinert ™ | 3M, St. Paul, | ˜N(CF₂CF₂CF₂CF₃)₃ | 0.21 |
| | FC-40* | MN | | |
| 2 | Vertrel ™ XF | DuPont, | CF₃CFHCFHCF₂CF₃ | 0.0026 |
| | | Fluoroproducts | | |
| | | Wilmington, DE | | |
| 5 | H-Galden ® | Ausimont USA, | HCF₂O(CF₂O)ₙ(CF₂CF₂O)ₘCF₂H | 0.0037 |
| | ZT 85 | Inc., Thorofare, | | |
| | | NJ | | |
| 12 | Solkane ™ | Solvay Fluorides | CF₃CH₂CF₂CH₃ | 0.0025 |
| | 365 mfc | St. Louis, MO | | |

*Fluorinert ™ FC-40 is a mixture of perfluoroinated amines of which N(CF₂CF₂CF₂CF₃)₃ is a major component.

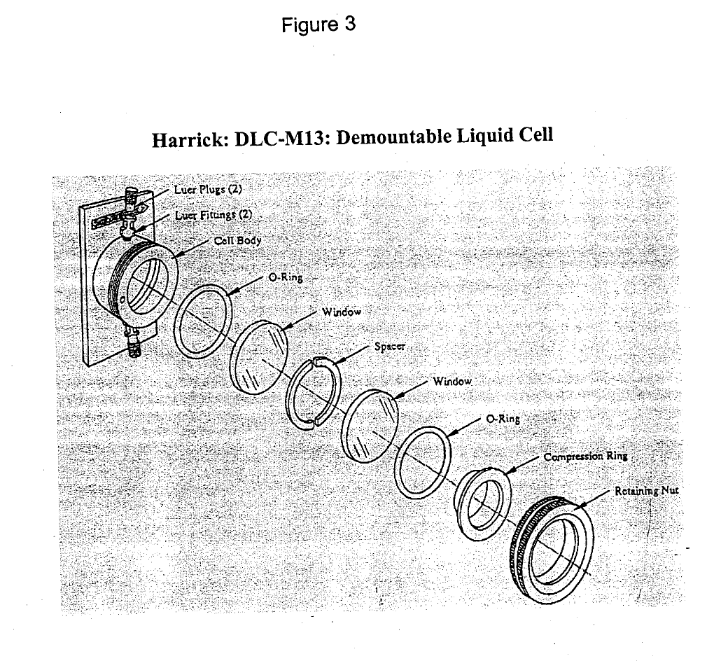

The transmission measurements of the fluid samples listed in Table 1 were made using a Harrick Scientific Corp. (Harrick Scientific Corporation 88 Broadway Ossining, NY) Demountable Liquid Cell model DLC-M13 as shown in FIG. 3. The DLC-M13 was mounted in a VUV-Vase model VU-302 spectroscopic ellipsometer, which is capable of performing transmission measurements (J. A. Woolman Co., Inc. Lincoln, Nebr.). The liquid specimen to be tested was held in a cell formed between parallel CaF2 windows by insertion of a Teflon®) ring between the windows. Teflon®) rings of 6 and 25 micrometer thickness were used, providing two optical path lengths through two aliquots of the same sample. While charging the cell, care was taken to avoid bubbles in the 8 mm diameter window aperture.

The optical absorbance, A (μm⁻¹), per micrometer of specimen thickness as defined in Equation 1, is defined for purposes herein as the base 10 logarithm of the ratio of the transmission of the CaF₂ windows at the test wavelength divided by the transmission at that wavelength of the test sample (windows plus experimental specimen) divided by the thickness (t) of the test specimen—in the case of the experiments reported herein, either 6 or 25 micrometers, as discussed hereinabove.

$$A ( {µm}^{- 1} ) = A / um = \frac{{Log}_{10} ⌊ {T}_{substrate} / {T}_{sample} ⌋}{t} . \qquad Equation 1$$

To eliminate the effect of multiple reflections in the case of the liquid samples employed herein, absorbance was determined using both the 6 and 25 μm cells. The spectral transmission was measured at both cell thicknesses (t₁ and t₂) and the incremental decrease in transmission (T₁ and T₂) with the increase in the sample's optical path length provides the optical absorbance/micrometer using Equation 2.

$$A / µm = \frac{{log}_{10} ( {T}_{1} ) - {log}_{10} ( {T}_{2} )}{{t}_{2} - {t}_{1}} . \qquad Equation 2$$

In further investigation it was found that, when irradiated by 157 nm laser radiation at an intensity and for a duration similar to those expected to be encountered in actual commercial practice, the organic compounds suitable for the practice of the present invention in their as-received or as-synthesized condition underwent photochemical darkening (PCD) and bubble formation at a rate which could limit the useful lifetime thereof in practical commercial use. Thus, there is considerable incentive for finding a means for increasing the useful lifetime of organic compounds intended for use in 157 nm or 193 nm photolithography, and for inhibiting the formation of bubbles.

One of skill in the art will appreciate that PCD and bubble formation are highly deleterious to the value in use of the transparent materials employed in photolithography. Photochemical instability at VUV wavelengths may be inherent in the candidate material for use in VUV photolithography, resulting in undesirable levels of PCD and/or bubbles; this is a particular issue at the very high photon energies associated with 157 nm irradiation. However, one of skill in the art will appreciate that even small levels of contaminants—some of which may be highly absorbing at the wavelength of interest—may exhibit the photochemical activity which leads to PCD and bubbles. It is thus of considerable interest to determine whether extraction of potential sources of photochemical activity may result in an improvement to PCD, bubble formation, or both.

Two particularly suspect photochemically active species at the short wavelengths of interest herein are oxygen and moisture because of their ubiquity in nature.

Upon further investigation it is found that the preferred organic compounds of the invention as received or as synthesized, exhibit a moisture content generally above 20 ppm and usually above 50 ppm and often above 200 ppm; and an oxygen content generally in the range 90 ppm. It is further found that when a means for extracting moisture from a liquid is applied to the organic compounds preferred for the practice of the present invention that the moisture content is readily reduced to below 20 ppm, preferably below 15 ppm, more preferably below 10 ppm, and occasionally and most preferably below 1 ppm. It is found surprisingly that the PCD rate at 157 nm and 193 nm of the thus prepared reduced-moisture compound is reduced many fold over the starting material.

It is also found that treatment of the fluorinated organic compounds suitable for the practice of the invention with a means effective for reducing oxygen concentration is also effective in reducing PCD as well as bubble formation.

In a preferred embodiment of the present invention there is provided a composition suitable for use in 157 nm or 193 nm lithography which exhibits an extended useful lifetime by virtue of a reduced PCD rate and reduced bubble formation over the as-received fluorinated organic compounds suitable for the practice of the present invention, said composition comprising less than 20 parts per million of water, less than 90 ppm oxygen, and one or more compounds selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{c}, and R_{f}^{c} are 1 to 3 carbon fluorocarbon radicals, linear or branched

in which there are more fluorines than hydrogens, no runs of adjacent C—H bonds longer than two are present, and no sequences with hydrogen on both sides of an ether oxygen (CH—O—CH) are present;

iii) CₙF₂ₙ₋ᵥ₊₂Hᵥ wherein n=2 to 10, v<n=1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

ix) cyclic, linear, or branched perfluorocarbon and hydrofluorocarbon amines, and ether-amines in which there are more fluorines than hydrogens, no runs of hydrogen longer than two (CH—CH), no runs of adjacent C—F bonds longer than 6 (CF—CF—CF—CF—CF—CF), and no C—H bonds immediately adjacent to either nitrogen or oxygen.

Preferably the composition of the invention comprises one or more compounds selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8, said composition having a moisture content of less than 20 ppm and an oxygen content of less than 90 ppm. More preferably, the composition of the invention comprises perfluorotributylamine, perfluoro-N-methymorpholine, CF₃CFHCFHCF₂CF₃, CF₃CH₂CF₂CH₃ or HCF₂O(CF₂O)ₙ(CF₂CF₂O)ₘCF₂H where n+m=2 to 6, or a mixture thereof, said composition having a moisture content of less than 20 ppm and an oxygen content of less than 90 ppm. The organic compound of the invention is preferably a liquid.

In another embodiment of the present invention is provided a process for the preparation of the composition of the invention. The liquid organic compounds preferred for the practice of the present invention are well-known known in the art, and may be prepared according to the methods hereinabove described with reference to the published methods therefor. In the process of the invention the liquid organic compound, or organic liquid, of the invention in its “as received” or “as synthesized” state is subject to one or more means for extracting photochemically active species. Methods known in the art for performing extractions of particular types of contaminants are suitable for the practice of the present invention, but care must be taken that these methods are executed under very clean conditions to avoid further contamination, thus substituting one problem for another.

In one embodiment of the process of the invention, the photochemically active species is moisture. Any means for extracting moisture as is known in the art is acceptable for the practice of the present invention. Suitable means include but are not limited to heating in an oven under vacuum, or under a desiccated purge gas, or both; heating in a recirculating air oven having desiccant beds; refluxing in the presence of a desiccated purge gas, sparging with a purge gas, preferably an inert gas such as nitrogen or argon; exposing said liquid to a desiccated atmosphere at room temperature or below; contacting said liquid with a desiccant such as molecular sieves; vaporizing said liquid and passing over a desiccant such as molecular sieves, followed by condensation; or contacting said liquid with chemical desiccants such as isocyanates and fractionally distilling. In the case of contacting said fluorinated organic compound with a desiccant it will normally be necessary to add a separation step upon completion of the extraction step. One of skill in the art will appreciate that not all methods of drying will be suitable for every compound suitable for the practice of the present invention. For example, if the organic liquid is flammable, a heating method may be less desirable than some other means. The inventors hereof do not contemplate any limitations on the methods of drying which may be employed to achieve the desired state of dryness with the proviso that the method employed not introduce more undesirable contamination than it removes, that the method not cause significant degradation of the compound being purified, and that the method be safely executed. Thus any method known to one of skill in the art for extracting moisture from organic liquids is suitable.

Preferred for the practice of the invention is to contact said preferred organic liquid with molecular sieves followed by filtration to separate the thereby desiccated organic liquid from said molecular sieves. Types 3A, 4A, and 5A molecular sieves are preferred because their cavities are of a size that favor the selective absorption of water from organic vapors and fluids.

In a further embodiment, the photochemically active species is oxygen. It will be understood by one of skill in the art that oxygen contamination represents an additional source of photochemical instability at the high energies of VUV radiation. Oxygen is of course closely associated with numerous degradation mechanisms in many materials from organics to metals. The technique of sparging with an inert gas, preferably nitrogen or argon, is found to be an effective means for removing oxygen from the compositions of the invention. Other methods suitable for removing oxygen include but are not limited to heating in an oven under vacuum, or under an oxygen free purge gas, contacting with an oxygen scavenger, repeated cycles of freezing, pulling a high vacuum and thawing, or vacuum distillation are all effective means for extracting oxygen from the fluorinated organic compounds suitable for use is the present invention. The inventors hereof do not contemplate any limitations on the methods of extracting oxygen which may be employed to achieve the desired oxygen concentration with the proviso that the method employed not introduce more undesirable contamination than it removes, that the method not cause significant degradation of the compound being purified, and that the method be safely executed. Thus any method known to one of skill in the art for extracting oxygen from organic liquids is suitable.

In the most preferred embodiment of the process of the invention the fluorinated organic compound is subject to extraction of photochemically active species, particularly oxygen and moisture, by sparging with an inert gas such as nitrogen or argon in combination with contacting the organic compound of the invention with molecular sieves.

Sparging is a preferred method for practicing the process of the invention, particularly for the removal of oxygen. One method for sparging found effective in the practice of the invention is as follows: A glove box is supplied with dry, low-oxygen-content nitrogen such as 99.998% or better nitrogen sold as a cylinder gas by Matheson or by the boil-off of liquid nitrogen. A liquid aliquot of about 10 ml is placed in a 20 ml glass scintillation vial. The sample is transferred into the nitrogen purged dry box. The vial is secured flat on the work surface, the plastic cap is removed from the vial, a disposable glass pipette lowered into the solvent and then nitrogen delivered via the pipette from the same dry, low-oxygen source as the glove box. Flow rate is adjusted to maintain vigorous bubbling of solvent short of causing the solvent to splash out of the vial. Vigorous sparging is continued for 30-60 seconds, long enough to significantly decrease oxygen content and possibly water content without major loss of solvent to evaporation.

For the purpose of the present invention, the terms “desiccated” as in “desiccated atmosphere” or “desiccated purge gas” means simply that the atmosphere or purge gas is sufficiently low in moisture content that it can function effectively to extract moisture from the preferred organic liquid of the invention. Preferably, a desiccated purge gas or desiccated atmosphere and the like will have actually been previously subject to an actual drying step prior to its use for extraction of moisture according to the present invention.

One of skill in the art will appreciate that while in a preferred embodiment, both oxygen and moisture are extracted from the fluorinated organic compound herein, extraction of either one but not both is also advantageous. In the practice of the present invention, extraction of any one photochemically active species will be beneficial whether or not any other photochemically active species which may be present is extracted or not. Thus, the inventors hereof contemplate embodiments wherein the moisture content is below 20 ppm, or the oxygen content is below 90 ppm, but wherein moisture and oxygen are not both within the desired range of concentration. These embodiments are less preferred.

This invention further includes a process for forming an optical image on a substrate, the process comprising:

radiating electromagnetic radiation from a source capable of radiating electromagnetic radiation in the range of 140-260 nm;

receiving said radiation on a target disposed to receive at least a portion of said radiation; and

wherein one or more optically transparent compositions is disposed between said radiation source and said target, at least one of said optically transparent compositions comprising a composition comprising less than 20 parts per million of water, less than 90 parts per million of oxygen, and one or more compounds selected from the group consisting of:

i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;

ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched

in which there are more fluorines than hydrogens, no runs of adjacent C—H bonds longer than two are present, and no CH₂CH₃ radicals are present;

and no sequences with hydrogen on both sides of an ether oxygen (CH—O—CH) are present;

iii) CₙF_{2n-y+2}Hᵥ wherein n=2 to 10, v<n+1, no runs of adjacent C—H bonds longer than two are present, no runs of adjacent C—F bonds longer than 6 are present, and no CH₂CH₃ radicals are present;

iv) CₙF₂ₙ₊₁CFHCFHCₘF₂ₘ₊₁ where n equals 1 to 4; and m equals 1 to 4;

v) CF₃CH₂CF₂CH₃;

vi) F[CF(CF₃)CF₂O]ₙCFHCF₃ where n=1 to 5;

vii) F[CF(CF₃)CF₂O]ₙCF₂CF₃ where n=1 to 5;

viii) HCF₂(OCF₂)ₙ(OCF₂CF₂)ₘOCF₂H where n+m=1 to 8; and,

Preferably said composition disposed between said light source and said target comprises one or more compounds selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8, said composition having a moisture content of less than 20 ppm, and oxygen concentration of less than 90 ppm. More preferably, said composition disposed between said light source and said target comprises perfluorotributylamine, perfluoro-N-methymorpholine, CF₃CFHCFHCF₂CF₃, CF₃CH₂CF₂CH₃ or HCF₂O(CF₂O)ₙ(CF₂CF₂O)ₘCF₂H where n+m=2 to 6, or a mixture thereof, said composition having a moisture content of less than 20 ppm. The organic compound of the invention is preferably a liquid.

It is expected that linear perfluoropolyethers of the structure X—R_{f}^{a}[OR_{f}^{b}]ₙOR_{f}^{c}Y will show high durability to UV radiation as molecular weights increase, the upper practical limit likely being inconveniently high viscosity. This would include F[CF(CF₃)CF₂O]ₙCFHCF₃ up to n=˜100, F[CF(CF)₃CF₂O]ₙCF₂CF₃ up to n=−100, HCF₂(OCF₂)ₙ(OCF₂CF₂)ₘOCF₂H up to n+m=100, and FCF₂(OCF₂)ₙ(OCF₂CF₂)ₘOCF₂F up to n+m=100.

In one embodiment of the photolithographic process of the invention, 157 nm radiation from a F₂ excimer laser transmitted through a photomask, typically comprising a chrome metal circuit patterned on glass by electron beam imaging forms an image of the circuit pattern on a photoresist. Various materials for photoresist compositions have been described in Introduction to Microlithography, Second Edition by L. F. Thompson, C. G. Willson, and M. J. Bowden, American Chemical Society, Washington, D.C., 1994.

The composition of the present invention may be employed in any number of ways which will cause it to become disposed between the light source and the target. Certain organic fluids are employed as solvents for the polymers in spin-coating operations. A solvent may serve to plasticize a polymeric film. A solvent may be employed in an adhesive formulation. Or, in a preferred embodiment of the invention herein, an organic fluid or gel may be employed as an immersion medium in immersion photolithography, as disclosed hereinabove. But, whether a polymer or a low molecular weight organic composition, if the composition resides in the light path between the source and the target, the composition needs to be transparent and durable.

In one preferred embodiment of the present invention the compositions of the invention are present in a pellicle employed in 157 nm photolithography. In a second preferred embodiment of the present invention, the compositions of the invention are present in a pellicle employed in 193 nm photolithography. A pellicle is a free standing polymer film, typically 0.8 micrometers in thickness which is placed over a photomask or other template pattern to keep particulate contamination out of the photomask object plane in order to reduce the defect level in the resulting image. The pellicle film must have high transparency at the lithographic wavelength for image formation and must exhibit a reasonable lifetime under repeated exposures to the lithographic irradiation. The term “reasonable” is of course a relative term determined by the economics of the particular application.

Fluorocarbon polymers are preferred for use in forming pellicles for use at VUV wavelengths. One method by which pellicles may be fabricated is by spin-coating from solution according to methods well-known in the art. As spun, the pellicle film may contain up to 10 wt % residual solvent which is not readily removed and may even be desirable in order to provide some plasticization to the film. It will be appreciated by one of skill in the art that a relatively small concentration of a solvent which lacks transparency at the lithographic wavelength may have a catastrophic effect on the transparency of the pellicle. Similarly, if the residual solvent exhibits photochemical instability, the durability of the pellicle film will be reduced. The compositions of the present invention exhibit a combination of high transparency and high radiation durability which makes them particularly useful as solvents for the preparation of pellicles for use in 157 nm or 193 nm photolithography.

Similar considerations and benefits will accrue to the employment of the compositions of the invention as solvents in the preparation of a photoresist layer by spin coating. The reason for this is that residual solvent is always left behind when spin coating resist films. If this residual solvent absorbs light strongly, light absorbtion at the top and bottom of the resist film become unequal enough to result in poor pattern development. Furthermore, if the residual solvent is photochemically unstable, the photoresist layer may exhibit defects upon exposure to VUV radiation. The fluids of this invention are highly attractive spin coating solvents because they will not noticeably increase absorption in photoresist layers when left behind as a residue.

In a further preferred embodiment, the composition of the present invention is employed in immersion photolithography as described by Switkes et al, op. cit. In immersion photolithography at least either the source or the target is immersed in the optically transparent composition of the invention. Preferably, both source and target are therein immersed. Among the requirements for the immersion medium that Switkes discusses are that it be transparent enough to allow a working distance of 10's of micrometers and that it have high radiation durability under 157 nm or 193 nm irradiation. The combination of high transparency and high radiation durability of the compositions of the present invention makes them particularly well-suited for immersion lithography applications at 157 nm or 193 nm wavelengths.

In still further embodiments, the compositions of the present invention are useful in the fabrication of sheets, layers, coatings, and films used in lenses, light guides, anti-reflective coatings and layers, windows, protective coatings, and glues suitable for use in 157 nm or 193 nm photolithography.

The compositions of the present invention are particularly useful in the formation of anti-reflection coatings and optical adhesives by virtue of low absorbance at 157 nm or 193 nm. The composition of the invention can be used to reduce the light reflected from the surface of a transparent substrate of a relatively higher index of refraction. This decrease in the reflected light, leads to a concomitant increase in the light transmitted through the transparent substrate material.

The compositions of the present invention are useful in the manufacture of transmissive optical elements, such as lenses and beam splitters, for use in the vacuum UV region.

These compositions may also be used as elements in a compound lens designed to reduce chromatic aberrations. At present only CaF₂ and possibly hydroxyl free silica are viewed as having sufficient transparency at 157 nm or 193 nm to be used in transmissive focussing elements. It is also commonly known (e.g, see R. Kingslake, Academic Press, Inc., 1978, Lens Design Fundamentals, p. 77) that by using a second material of different refractive index and dispersion, an achromatic lens can be created. By using the composition of the present invention in conjunction with CaF₂, it is expected that an achromatic lens can be constructed from this and other similar materials described in this application.

The extraction methods herein described, particularly for moisture and oxygen, are particularly useful for preparing fluorinated organic liquids for use in immersion lithography. The extraction methods herein taught are not limited to the specific compositions herein disclosed, but may be applied with excellent results to any fluorinated organic liquid contemplated for use as the immersion medium for immersion lithography in the VUV. Thus, even less preferred fluorinated organic compositions than those specifically disclosed herein, such as those exhibiting absorbance/micrometer up to 5, will exhibit improvements in PCD and bubble formation when extracted according to the process hereinabove described. By application of the methods herein, the moisture content of any such liquid contemplated can be reduced to below 20 ppm, and the oxygen content, to below 90 ppm.

It is found in the practice of the present invention that in some cases the measured PCD rate is dependent upon the dose received, with the highest rate being recorded for low initial doses. It is further found in the practice of the invention that PCD does not proceed indefinitely until the transparency has virtually disappeared. In some cases instead darkening occurs at a decreasing rate with increasing dose until an asymptote still at high transmission levels is approached and no further darkening is observed with increasing dose. It is further found in the practice of the invention that at least in certain cases, a cessation of exposure to 157 nm irradiation after the asymptotic level is reached results in further darkening. However, upon re-exposure to 157 nm radiation the degree of darkening is actually reduced and again the asymptotic level of transparency is re-achieved.

These phenomena are illustrated in certain specific embodiments of the invention hereinbelow.

The present invention is further described but not limited to the following specific embodiments.

### EXAMPLES

For the purpose of the examples hereinbelow, the absorbance of a test specimen is determined prior to laser irradiation, and then again after laser irradiation at 157 nm, using the methods and equipment described hereinabove with the exception that only the 6 μm or 25 μm cell was used, as specified in Tables 2 and 3. The dose of 157 nm radiation is determined according to the power output of the laser and the duration of the exposure. The difference between the two absorption readings is divided by the dosage received to give a parameter defined for the purposes herein to be the linear PCD rate. For the purpose of comparing one specimen to another, the linear PCD rate is then employed. This is referred to herein as the “10% PCD” dosage.

To calculate the PCD rate, we calculate the induced absorbance/um divided by the given irradiation dose (D). These are calculated from Equation 3 where T₁ is the initial transmission for a cell of thickness t and T₂ is the final transmission after a dose D.

$${A}_{i} / D = \frac{{log}_{10} ( {T}_{1} ) - {log}_{10} ( {T}_{2} )}{t} / D . \qquad Equation 3$$

The 10% PCD Lifetime, in units of Joules/cm² dose of 157 nm radiation is calculated from the ratio of the induced absorption necessary to produce a transmission drop, ΔT, of 10% for a sample of thickness t=0.8 micrometers, as given by Equation 4. An increase in the 10% PCD lifetime corresponds to increased radiation durability.

$$Lifetime = \frac{A {.}_{i}}{PCD rate} = \frac{{Log}_{10} ( \frac{{T}_{init}}{( {T}_{init} - Δ T )} )}{t PCD rate} . \qquad Equation 4$$

Water concentration was determined according to the Karl Fischer method commonly employed in the art. The effect of drying over molecular sieves of the preferred compositions of the invention is indicated in Table 4.

Laser irradiation at 157 nm was accomplished inside a nitrogen purged dry-box using an Optex F₂ excimer laser made by Lambda Physik (Lambda Physik USA, Inc, Fort Lauderdale, Fla.). In practice the DCL cell hereinabove described was simply moved from the ellipsometer described hereinabove to a holder in the dry box putting the test sample into the path of the laser. The laser pulse rate was 50 hz, putting out 1 mJ/cm²/pulse energy density or 3 Joules/cm²/minute. All doses reported here are Joules per cm² area irradiated. The reported doses are corrected for the losses associated with the CaF₂ windows so that the doses represent the actual dose incident upon the sample itself, not the total dose incident upon the measurement cell.

As in all experimental measurements, the accuracy of the measured values is a function of the sample and measurement apparatus. The inherent sensitivity of spectral transmission and absorbance measurements is affected by the optical path length of the sample, and the transmission drop that occurs as light transmits through the sample in the measurement. As the transmission drop decreases, the accuracy of the absorbance measurement decreases. A transmission difference of ˜0.1% is near the limit of the measurement method. In such a case, a thicker sample, with a longer path length, is required to keep the measured transmission drop larger than the instrument's sensitivity.

TABLE 2
10% PCD Lifetime and moisture content of as-received organic
compounds

| | | | | 10% | Moisture |
|---|---|---|---|---|---|
| | | | | PCD | Content |
| | | Thick- | Initial | Life- | (as |
| | | ness | Dose | time (J/ | received) |
| Ex. | Solvent | um | (J/cm²) | cm²) | ppm |
| Comp. | CF₃CFHCFHCF₂CF₃ | 6 | 3 | 9.9 | 72 |
| Ex 2 | Vertrel ™ XF | | | | |
| Comp. | CF₃CFHCFHCF₂CF₃ | 6 | 6 | 52.7 | 72 |
| Ex. 3 | Vertrel ™ XF | | | | |
| Comp. | CF₃CFHCFHCF₂CF₃ | 6 | 20 | 47.5 | 72 |
| Ex. 4 | Vertrel ™ XF | | | | |
| Comp. | HCF₂O(CF₂O)ₙ | 25 | 15 | Bubble | 257 |
| Ex. 5 | (CF₂CF₂O)ₘCF₂H | | | | |
| | H-Galden ® ZT 85 | | | | |
| Comp. | HCF₂O(CF₂O)ₙ | 25 | 30 | Bubble | 257 |
| Ex. 6 | (CF₂CF₂O)ₘCF₂H | | | | |
| | H-Galden ® ZT 85 | | | | |
| Comp. | HCF₂O(CF₂O)ₙ | 25 | 15 | Bubble | 257 |
| Ex. 7 | (CF₂CF₂O)ₘCF₂H | | | | |
| | H-Galden ® ZT 85 | | | | |

For the purpose of the present invention, the experimental comparisons made herein were determined for the initial PCD rate measured in each particular case. The initial dosage was not always the same.

TABLE 3
10% PCD Lifetimes of Treated Samples

| | | | | | 10% | |
|---|---|---|---|---|---|---|
| | | | | | PCD | |
| | | Thick- | Pre- | | Life- | Water |
| | | ness | treat- | Dose | time | Content |
| Ex. | Solvent | um | ment | (J/cm²) | (J/cm²) | (ppm) |
| 1 | Vertrel ™ XF | 6 | Sparge | 6 | 128.2 | 0.71 |
| 2 | Vertrel ™ XF | 6 | Sparge | 20 | 200.4 | 0.71 |
| 3 | H-Galden ® ZT 85 | 25 | Sparge | 6 J | 497 | 0.94 |
| 4 | H-Galden ® ZT 85 | 25 | Mol. | 12.5 | 457 | 0.94 |
| | | | Sieve | | | |
| 5 | H-Galden ® ZT 85 | 25 | Mol. | 25.4 | 868 | 0.94 |
| | | | Sieve | | | |
| 6 | H-Galden ® ZT 85 | 25 | Mol. | 12.75 J | 569 | 0.94 |
| | | | Sieve | | | |

TABLE 4
Effect of Drying over 3A Molecular Sieves

PPM H₂O

| Ex. # | Description | As received | Dried |
|---|---|---|---|
| 7 | H-Galden ® | 257 | 0.94 |
| 8 | Solkane ™ 365 mfc | 218 | 12 |
| 9 | Vertrel ™ XF | 72 | 0.71 |

### Comparative Example 1.

Liquid sample cells having CaF₂ windows spaced 6 μm and 25 μm apart were used. Transmitted light intensities were measured with the cells empty and with the cells filled with ˜N(CF₂CF₂CF₂CF₃)₃, Fluorinert™ FC-40. ˜N(CF₂CF₂CF₂CF₃)₃, Fluorinert™ FC-40 was found have A/μm=0.21 at 157 nm.

A sample of FC-40 as received was loaded into a liquid sample cell with 6 micrometer spacers, and then irradiated with 1.1 Joules/cm² of 157 nm radiation. This material had a 10% PCD lifetime of <0.2 Joules/cm²

### Comparative Example 2.

Liquid sample cells having CaF₂ windows spaced 6 μm and 25 μm apart were used. Transmitted light intensities were measured with the cells filled with Vertrel® XF. Vertrel® XF was found have A/μm=0.0026 at 157 nm.

A sample of Vertrel® XF as received was loaded into a liquid sample cell with 6 micrometer spacers, and then irradiated with 3 Joules/cm² of 157 nm radiation. This sample showed a 10% PCD lifetime of 9.9 Joules/cm².

### Comparative Example 3 and Example 1

A sample of Vertrel® XF as received was loaded into a liquid sample cell with 6 micrometer spacers, and then irradiated with 6 Joules/cm² of 157 nm radiation. This sample showed a 10% PCD lifetime of 52.7 Joules/cm².

A sample of Vertrel® XF which was vigorously sparged for 1 minute was loaded into a liquid sample cell with 6 micrometer spacers, and then irradiated with 6 Joules/cm² of 157 nm radiation. This sample showed a 10% PCD lifetime of 128.2 Joules/cm².

### Comparative Example 4 and Example 2

A sample of Vertrel® XF as received was loaded into a liquid sample cell with 6 micrometer spacers, and then irradiated with 20 Joules/cm² of 157 nm radiation. This sample showed a 10% PCD lifetime of 47.5 Joules/cm².

A sample of Vertrel® XF which was vigorously sparged for 1 minute was loaded into a liquid sample cell with 6 micrometer spacers, and then irradiated with 20 Joules/cm² of 157 nm radiation. This sample showed a 10% PCD lifetime of 200.4 Joules/cm².

### Example 3

Liquid sample cells having CaF₂ windows spaced 6 micrometer and 25 micrometer apart were used. Transmitted light intensities were measured with the cells filled with H-Galden® ZT 85. H-Galden® ZT 85 was found have A/μm=0.0037 at 157 nm.

A sample of H-Galden® ZT 85 which was vigorously sparged for 1 minute was loaded into a liquid sample cell with 25 micrometer spacers, and then irradiated with 6 Joules/cm² of 157 nm radiation. This sample showed a 10% PCD lifetime of 497 Joules/cm².

### Comparative Example 5.

A sample of H-Galden® ZT 85 as received was loaded into a liquid sample cell with 25 micrometer spacers, and then irradiated with 15 Joules/cm² of 157 nm radiation. Bubbles formed in the liquid cell.

### Comparative Example 6.

A sample of H-Galden® ZT 85 as received was loaded into a liquid sample cell with 25 micrometer spacers, and then irradiated with 30 Joules/cm² of 157 nm radiation. Bubbles formed in the liquid cell COMPARATIVE EXAMPLE 7.

A sample of H-Galden® ZT 85 with no pretreatment was loaded into a liquid sample cell with 25 micrometer spacers, and then irradiated with 30 Joules/cm² of 157 nm radiation. Bubbles formed in the liquid cell.

### Example 4

A Hastelloy tube about two feet long by 1 inch in diameter was loaded with 3A molecular sieves, placed in a 310° C. tube oven, and purged with nitrogen gas overnight. The next morning the nitrogen purge gas was first passed through a liquid nitrogen chilled trap to make sure it was reasonably dry for the remainder of the experiment. The tube furnace was then turned off and the molecular sieves allowed to return to room temperature while maintaining the purge of dry nitrogen. About 1-2 grams of dry 3A molecular sieves were poured directly out the back end of the Hastelloy tube into a one ounce sample vial already containing 10 ml of H-Galden® ZT 85 solvent. The vial was immediately capped with a rubber septum and then rolled overnight to make sure of good contact between the solvent and the 3A molecular sieves.

The H-Galden® ZT 85 sample was filtered using a 0.45 micron glass syringe filter. A sample of thus treated H-Galden® ZT 85 was loaded into a liquid sample cell with 25 micrometer spacers, and then irradiated with 157 nm radiation. The irradiation was done in an initial dose of 12.5 Joules/cm² followed by a final dose of 36 Joules/cm², to produce a total dose of 48.5 Joules/cm². The 10% PCD lifetime over the initial dose was 457 Joules/cm².

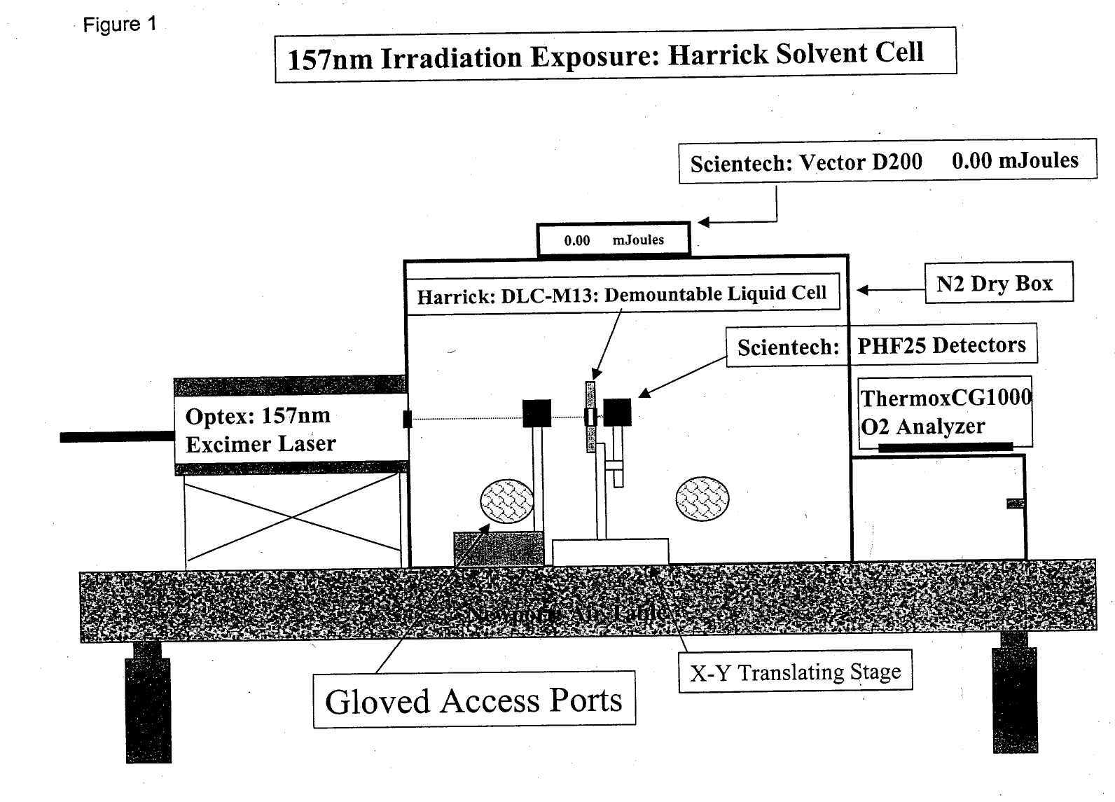

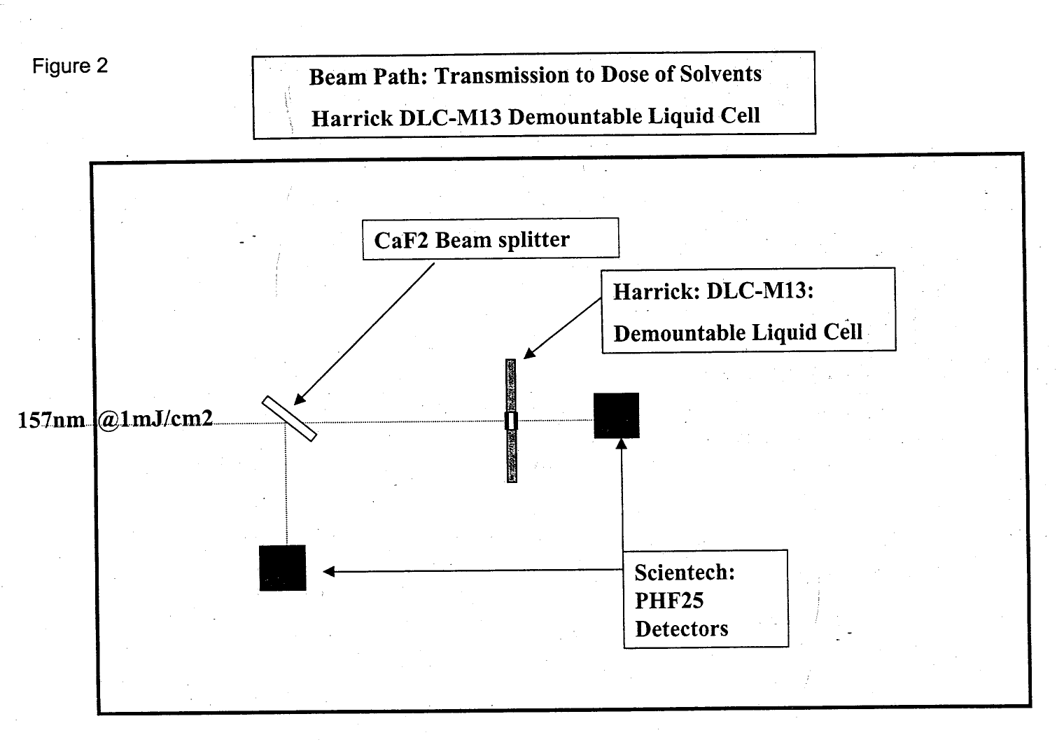

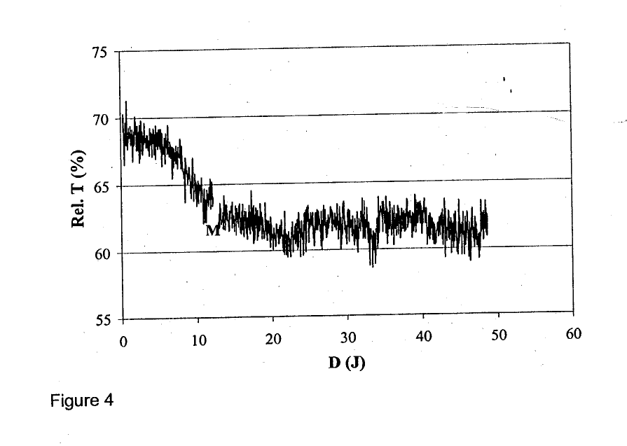

The relative transmission to dose for is shown in FIG. 4. Pyroelectric detectors (Scientech PHF-25, Scientech, Inc. Boulder, Colo.) and a power meter/ratiometer (Scientech model Vector D200) which were built in to the laser irradiation set-up as shown in FIG. 1, were used to measure the in situ variation of the relative sample transmission with increasing laser radiation dose. FIG. 4, shows a rapid decrease in the transmission during the initial 12.5 Joule dose. After the initial dose the sample had been removed at point M for a spectroscopic measurement and then replaced in the laser irradiation apparatus for administration of the subsequent irradiation dose.

The large initial transient in the photochemical darkening, which then stabilizes beyond a certain dose as shown by the relative transmission to dose in FIG. 4 demonstrated that for applications which require stability in the transmission over long doses, for example immersion lithography or a liquid pellicle, then preconditioning of the material directly prior to use may produce very long and stable transparency.

### EXAMPLE 5

The methods of Example 4 were repeated again using H-Galden® ZT85. The laser irradiation was done in an initial dose of 25.4 Joules/cm² followed by a final dose of 87.5 Joules/cm², to produce a total dose of 113 Joules/cm². The 10% PCD lifetime over the initial 25.4 Joule dose was 868 Joules/cm².

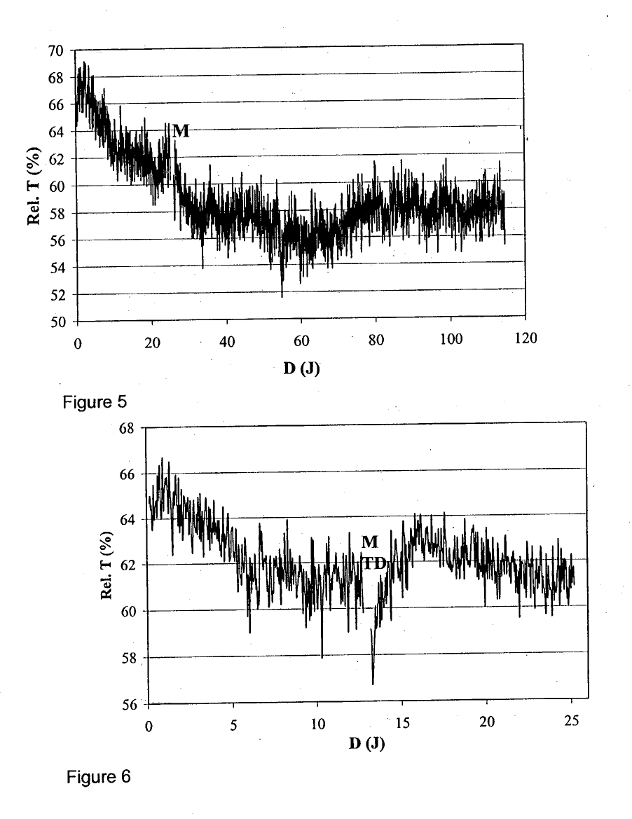

The relative transmission to dose was determined as in Example 4 and is shown in FIG. 5 where M represents the same interruption in irradiation. The relative transmission to dose during the final 87.5 Joule dose was nearly constant.

### Example 6

The methods and materials of Example 4 were repeated to prepare a specimen of H-Galden® ZT85 for testing. The irradiation was done in an initial dose of 12.75 Joules/cm² followed by a final dose of 12.25 Joules/cm², to produce a total dose of 25 Joules/cm². The 10% PCD lifetime over the initial 12.75 Joule dose was 569 Joules/cm².

The relative transmission to dose is shown in FIG. 6. M represents the same relatively short interruption of irradiation as in FIGS. 4 and 5. TD represents an interruption of 16 hours between the initial and final doses.

### Example 7

A one ounce sample vial was loaded with 10 ml of H-Galden® ZT 85 solvent and immediately capped with a rubber septum. Karl Fisher analysis of this H-Galden®) ZT 85 found 257 ppm of water. H-Galden® ZT 85 as supplied by the vendor and as handled in ordinary glassware under ordinary laboratory conditions can be thus be expected to contain about 257 ppm of water.

A Hastelloy tube about two foot long by 1 inch in diameter was loaded with 3A molecular sieves, placed in a 310° C. tube oven, and purged with nitrogen gas overnight. The next morning the nitrogen purge gas was first passed through a liquid nitrogen chilled trap to make sure it was reasonably dry for the remainder of the experiment. The tube furnace was then turned off and the molecular sieves allowed to return to room temperature while maintaining the purge of dry nitrogen. About 1-2 grams of dry 3A molecular sieves were poured directly out the back end of the Hastelloy tube into a one ounce sample vial already containing 10 ml of H-Galden® ZT 85 solvent. The vial was immediately capped with a rubber septum and then rolled overnight to make sure of good contact between the solvent and the 3A molecular sieves. A sample syringed out for Karl Fisher analysis analyzed for 0.94 ppm water.

### Example 8

A one ounce sample vial was loaded with 10 ml of Solkane™ 365 mfc solvent and immediately capped with a rubber septum. Karl Fisher analysis of this Solkane™ 365 mfc found 218 ppm of water. Solkane™ 365 mfc as supplied by the vendor and as handled in ordinary glassware under ordinary laboratory conditions can be thus be expected to contain about 218 ppm of water.

A Hastelloy tube about two foot long by 1 inch in diameter was loaded with 3 A molecular sieves, placed in a 310° C. tube oven, and purged with nitrogen gas overnight. The next morning the nitrogen purge gas was first passed through a liquid nitrogen chilled trap to make sure it was reasonably dry for the remainder of the experiment. The tube furnace was then turned off and the molecular sieves allowed to return to room temperature while maintaining the purge of dry nitrogen. About 1-2 grams of dry 3 A molecular sieves were poured directly out the back end of the Hastelloy tube into a one ounce sample vial already containing 10 ml of Solkane™ 365 mfc solvent. The vial was immediately capped with a rubber septum and then rolled overnight to make sure of good contact between the solvent and the 3 A molecular sieves. A sample syringed out for Karl Fisher analysis analyzed for 12 ppm water.

### Example 9

A one ounce sample vial was loaded with 10 ml of Vertrel™ XF solvent and immediately capped with a rubber septum. Karl Fisher analysis of this Vertrel™ XF found 72 ppm of water. Vertrel™ XF as supplied by the vendor and as handled in ordinary glassware under ordinary laboratory conditions can be thus be expected to contain about 72 ppm of water.

A Hastelloy tube about two foot long by 1 inch in diameter was loaded with 3A molecular sieves, placed in a 310° C. tube oven, and purged with nitrogen gas overnight. The next morning the nitrogen purge gas was first passed through a liquid nitrogen chilled trap to make sure it was reasonably dry for the remainder of the experiment. The tube furnace was then turned off and the molecular sieves allowed to return to room temperature while maintaining the purge of dry nitrogen. About 1-2 grams of dry 3 A molecular sieves were poured directly out the back end of the Hastelloy tube into a one ounce sample vial already containing 10 ml of Vertrel™ XF solvent. The vial was immediately capped with a rubber septum and then rolled overnight to make sure of good contact between the solvent and the 3 A molecular sieves. A sample syringed out for Karl Fisher analysis analyzed for 0.71 ppm water.

What is claimed is:

1. An organic composition characterized by an absorbance/micrometer of <1 at wavelengths from 140 to 260 nm, said composition comprising less than 20 parts per million of water, less than 90 ppm of oxygen, and one or more compounds selected from the group consisting of:
i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;
ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched
in which there are more fluorines than hydrogens, no runs of adjacent C—H bonds longer than two are present, no —CH₂CH₃ radicals are present and no sequences with hydrogen on both sides of an ether oxygen (CH—O—CH) are present;
iii) CₙF₂ₙ₋ᵥ₊₂Hᵥ wherein n=2 to 10, v<n+1, the number of fluorines equals or exceeds the number of hydrogens, no runs of adjacent C—H bonds longer than two are present, no runs of adjacent C—F bonds longer than 6 are present, and no CH₂CH₃ radicals are present;
iv) CₙF₂ₙ₊₁CFHCFHCₘF₂ₘ₊₁ where n equals 1 to 4; and m equals 1 to 4;
v) CF₃CH₂CF₂CH₃;
vi) F[CF(CF₃)CF₂O]ₙCFHCF₃ where n=1 to 5;
vii) F[CF(CF₃)CF₂O]ₙCF₂CF₃ where n=1 to 5;
viii) HCF₂(OCF₂)ₙ(OCF₂CF₂)ₘOCF₂H where n+m=1 to 8; and,
ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present, no runs of adjacent C—F bonds longer than 6 (CF—CF—CF—CF—CF—CF), and no C—H bonds immediately adjacent to either nitrogen or oxygen.

2. The composition of claim 1 wherein said one or more compounds are selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8.

3 The composition of claim 1 wherein said one or more compounds are selected from the group consisting of perfluorotributylamine, perfluoro-N-methymorpholine, CF₃CFHCFHCF₂CF₃, CF₃CH₂CF₂CH₃ and HCF₂O(CF₂O)ₙ(CF₂CF₂O)ₘCF₂H where n+m=2 to 6.

4. The composition of claim 1 wherein at least one of said one or more compounds is a liquid.

5. A process for preparing an organic composition characterized by an absorbance/micrometer of <1 at wavelengths from 140 to 260 nm, comprising subjecting to treatment with one or more means for extracting one or more photochemically active species, a compound selected from the group consisting of:
i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;
ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched
in which there are more fluorines than hydrogens, no runs of adjacent C—H bonds longer than two are present, no —CH₂CH₃ radicals are present and no sequences with hydrogen on both sides of an ether oxygen (CH—O—CH) are present;
iii) CₙF₂ₙ₋ᵥ₊₂Hᵥ wherein n=2 to 10, v<n+1, no runs of adjacent C—H bonds longer than two are present, no runs of adjacent C—F bonds longer than 6 are present, and no CH₂CH₃ radicals are present;
iv) CₙF₂ₙ₊₁CFHCFHCₘF₂ₘ₊₁ where n equals 1 to 4; and m equals 1 to 4;
v) CF₃CH₂CF₂CH₃;
vi) F[CF(CF₃)CF₂O]ₙCFHCF₃ where n=1 to 5;
vii) F[CF(CF₃)CF₂O]ₙCF₂CF₃ where n=1 to 5;
viii) HCF₂(OCF₂)ₙ(OCF₂CF₂)ₘOCF₂H where n+m=1 to 8; and,
ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen;
at least until the desired concentration of said one or more photochemically active species is achieved.

6. The process of claim 5 wherein said one or more photochemically active species comprises moisture, and the desired concentration is below 20 parts per million.

7. The process of claim 5 wherein said one or more photochemically active species comprises oxygen, and the desired concentration is below 90 parts per million.

8. The process of claim 5 wherein said one or more photochemically active species comprises moisture and oxygen and the desired concentrations are below 20 parts per million and below 90 parts per million, respectively.

9. The process of claim 5 wherein said one or more compounds are selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8.

10. The process of claim 5 wherein said one or more compounds are selected from the group consisting of perfluorotributylamine, perfluoro-N-methymorpholine, CF₃CFHCFHCF₂CF₃, CF₃CH₂CF₂CH₃ and HCF₂O(CF₂O)ₙ(CF₂CF₂O)ₘCF₂H where n+m=2 to 6.

11. The process of claim 5 wherein at least one of said one or more compounds is a liquid.

12. The process of claim 5 wherein said means comprises contacting said compound with molecular sieves.

13. The process of claim 5 wherein said means comprises sparging with an inert gas.

14. The process of claim 5 wherein said means comprises contacting said compound with molecular sieves and sparging said compound with an inert gas.

15. A process for forming an optical image on a substrate, the process comprising:
a) radiating electromagnetic radiation from source capable of radiating electromagnetic radiation in the range of 140-260 nm;
b) receiving said radiation on a target disposed to receive at least a portion of said radiation; and
wherein one or more optically transparent compositions is disposed between said radiation source and said target, at least one of said optically transparent compositions comprising a composition comprising less than 20 parts per million of water, less than 90 parts per million of oxygen, and one or more compounds selected from the group consisting of:
i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;
ii) X—R_{f}^{a}[OR_{f}^{b}]nOR_{f}^{c}Y wherein X and Y can be hydrogen or fluorine and R_{f}^{a}, R_{f}^{b}, and R_{f}^{c} are 1 to 3 carbon fluorocarbon radicals, linear or branched
in which there are more fluorines than hydrogens, no runs of adjacent C—H bonds longer than two are present, no —CH₂CH₃ radicals are present and no sequences with hydrogen on both sides of an ether oxygen (CH—O—CH) are present;
iii) CₙF₂ₙ₋ᵥ₊₂Hᵥ wherein n=2 to 10, v<n+1, no runs of adjacent C—H bonds longer than two are present, no runs of adjacent C—F bonds longer than 6 are present, and no CH₂CH₃ radicals are present;
iv) CₙF₂ₙ₊₁CFHCFHCₘF₂ₘ₊₁ where n equals 1 to 4; and m equals 1 to 4;
v) CF₃CH₂CF₂CH₃;
vi) F[CF(CF₃)CF₂O]ₙCFHCF₃ where n 1 to 5;
vii) F[CF(CF₃)CF₂O]ₙCF₂CF₃ where n=1 to 5;
viii) HCF₂(OCF₂)ₙ(OCF₂CF₂)ₘOCF₂H where n+m=1 to 8; and,
ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen.

16. The process of claim 15 wherein said one or more compounds are selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8.

17. The process of claim 15 wherein said one or more compounds are selected from the group consisting of perfluorotributylamine, perfluoro-N-methymorpholine, CF₃CFHCFHCF₂CF₃, CF₃CH₂CF₂CH₃ and HCF₂O(CF₂O)ₙ(CF₂CF₂O)ₘCF₂H where n+m=2 to 6.

18. The process of claim 15 wherein at least one of said one or more compounds is a liquid.

19. The process of claim 15 wherein said at least one of said radiation source and said target are immersed in said optically transparent composition.

20. The process of claim 15 wherein both radiation source and target are immersed in said optically transparent composition.

21. A process for forming an optical image on a substrate, the process comprising:
radiating electromagnetic radiation from a source capable of
radiating electromagnetic radiation in the range of 140-260 nm;
receiving said radiation on a target disposed to receive at least a portion of said radiation; and
wherein one or more optically transparent compositions is disposed between said radiation source and said target, at least one of said optically transparent compositions comprising a composition treated with one or more means for extracting one or more photochemically active species, the composition comprising one or more compounds selected from the group consisting of:
i) cyclic, linear, or branched hydrofluorocarbons having 2 to 10 carbon atoms in which there are more fluorines than hydrogen, no runs of adjacent C—H bonds longer than two (CH—CH), no runs of adjacent C—F bonds longer than 6 (CF—CF—CF—CF—CF—CF), and no —CH₂CH₃ radicals;
ii) X—R_{f}^{a}[OR_{f}^{b]nOR}_{f}^{c}Y wherein X and Y can be hydrogen or fluorine and R_{f}^{a}, R_{f}^{b}, and R_{f}^{c} are 1 to 3 carbon fluorocarbon radicals, linear or branched
in which there are more fluorines than hydrogens, no runs of adjacent C—H bonds longer than two are present, no —CH₂CH₃ radicals are present and no sequences with hydrogen on both sides of an ether oxygen (CH—O—CH) are present;
iii) CₙF_{2n-y+2}Hᵥ wherein n=2 to 10, v<n+1, no runs of adjacent C—H bonds longer than two are present, no runs of adjacent C—F bonds longer than 6 are present, and no CH₂CH₃ radicals are present;
iv) CₙF₂ₙ₊₁CFHCFHCₘF₂ₘ₊₁ where n equals 1 to 4; and m equals 1 to 4;
v) CF₃CH₂CF₂CH₃;
vi) F[CF(CF₃)CF₂O]ₙCFHCF₃ where n=1 to 5;
vii) F[CF(CF₃)CF₂O]ₙCF₂CF₃ where n=1 to 5;
viii) HCF₂(OCF₂)ₙ(OCF₂CF₂)ₘOCF₂H where n+m=1 to 8; and,
ix) cyclic, linear, or branched perfluorocarbon and hydrofluorocarbon amines, and ether-amines in which there are more fluorines than hydrogens, no runs of hydrogen longer than two (CH—CH), no —CH₂CH₃ radicals are present and no runs of adjacent C—F bonds longer than 6 (CF—CF—CF—CF—CF—CF), and no C—H bonds immediately adjacent to either nitrogen or oxygen.

22. The process of claim 21 wherein the photochemically active species comprises moisture, and the desired concentration is below 20 parts per million.

23. The process of claim 21 wherein the photochemically active species comprises oxygen, and the desired concentration is below 90 parts per million.

24. The process of claim 21 wherein the one or more photochemically active species comprise moisture and oxygen and the desired concentrations are below 20 parts per million and below 90 parts per million, respectively.

25. The process of claim 21 wherein said one or more compounds are selected from the group consisting of perfluorotributylamine, perfluoro-N-methymorpholine, CₙF₂ₙ₊₁CFHCFHCₘF₂ₘ₊₁ where n equals 1 to 4; and m equals 1 to 4 and HCF₂(OCF₂)ₙ(OCF₂CF₂)ₘOCF₂H where n+m=1 to 8.

26. The process of claim 21 wherein said one or more compounds are selected from the group consisting of perfluorotributylamine, perfluoro-N-methymorpholine, CF₃CFHCFHCF₂CF₃, CF₃CH₂CF₂CH₃ and HCF₂O(CF₂O)ₙ(CF₂CF₂O)ₘCF₂H where n+m=2 to 6.

27. The process of claim 21 wherein at least one of said one or more compounds is a liquid.

28. The process of claim 21 wherein said means comprises contacting said compound with molecular sieves.

29. The process of claim 21 wherein said means comprises sparging with an inert gas.

30. The process of claim 21 wherein said means comprises contacting said compound with molecular sieves and sparging said compound with an inert gas.

31. The process of claim 21 wherein at least one of said one or more compounds is a liquid.

32. The process of claim 21 wherein said at least one of said radiation source and said target are immersed in said optically transparent composition.

33. The process of claim 21 wherein both radiation source and target are immersed in said optically transparent composition.

34. A process for forming an optical image on a substrate, the process comprising:
radiating electromagnetic radiation from a source capable of radiating electromagnetic radiation in the range of 140-260 nm;
receiving said radiation on a target disposed to receive at least a portion of said radiation; and
wherein at least one of said target or said source is immersed in one or more optically transparent fluorinated organic liquids characterized by an absorbance per micrometer of <5 disposed between said radiation source and said target, at least one of said optically transparent fluorinated organic compounds having been subject to treatment with one or more means for extracting one or more photochemically active species.

35. The process of claim 34 wherein said one or more photochemically active species comprises moisture, and the desired concentration is below 20 parts per million.

36. The process of claim 34 wherein said one or more photochemically active species comprises oxygen, and the desired concentration is below 90 parts per million.

37. The process of claim 34 wherein said one or more photochemically active species comprises moisture and oxygen and the desired concentrations are below 20 parts per million and below 90 parts per million, respectively.
